(19) United States
(12) Patent Application Publication
(10) Pub. No.: US 2021/0302198 A1
(43) Pub. Date: Sep. 30, 2021

(54) LOAD MONITORING AND CONTROL BY A BUILDING AUTOMATION SYSTEM

(71) Applicant: Melink Solar & Geo, Inc., Milford, OH (US)

(72) Inventors: Stephen Melink, Cincinnati, OH (US); Seth Parker, Milford, OH (US)

(21) Appl. No.: 17/212,217

(22) Filed: Mar. 25, 2021

Related U.S. Application Data
(60) Provisional application No. 62/994,512, filed on Mar. 25, 2020.

(51) Int. Cl. G01D 4/00; H02J 13/00

(52) U.S. Cl. CPC G01D 4/002; G01R 22/063; H02J 13/00016

(57) ABSTRACT

A building automation system is disclosed. Sensors positioned in the building measure a corresponding load parameter. Each load parameter is indicative as to a current electric utility demand of the building based on current energy consumption of the loads. A controller monitors each load parameter to determine whether any load parameter deviates beyond the corresponding load parameter threshold. The controller activates a graduated action when each load parameter deviates beyond the corresponding load parameter threshold to automatically adjust the current energy consumption of the corresponding load that is deviated beyond the corresponding load parameter threshold to maintain the current electric utility demand within an electric utility demand threshold. The electric utility demand threshold is a peak demand allocated to the building by an electric utility to ensure that the peak demand for energy consumption of the building is satisfied.

### CROSS-REFERENCE TO RELATED APPLICATIONS

The present application is a U.S. Nonprovisional Application which claims the benefit of U.S. Provisional Application No. 62/994,512 filed on Mar. 25, 2020 which is incorporated herein by reference in its entirety.

### BACKGROUND

### Field of Disclosure

The present disclosure generally relates to a building automation system and specifically to load parameter monitoring by the building automation system and automatic adjustment of the operation of the loads associated with a building in response to the load parameter monitoring to the maintain the electric utility demand of the building within an electric utility demand threshold.

### Related Art

Electric utilities charge commercial buildings for both the electric energy consumed by the commercial building but also for the electric utility demand of the commercial building. The electric energy consumed is measured in kW/h and such electric energy consumed is then typically charged to the commercial building by the kW/h each month. However, the electric utility demand of the commercial building is the peak demand of electric energy measured in kW that the commercial building requires during any time of energy consumption. The electric utility then provides the electric utility demand in kW to the commercial building such that sufficient electric energy is available to the commercial building to consume whether the commercial building is operating at peak demand or not. The electric utility then charges the commercial building for that available electric utility demand regardless as to the amount of the actual available electric utility demand that the commercial building consumes.

Conventional approaches to reducing electric energy charges allocated from an electric utility focus on the reduction of electric energy consumed by the commercial building. In doing so, the quantity of kW/h consumed by the commercial building is sought to be decreased and thereby decreasing the amount of kW/h billed by the electric utility to the commercial building. However, 50% of the charges from an electric utility can be represented simply by the electric utility demand in kW provided by the electric utility. Limiting the focus in reducing the electric energy consumed by the commercial building to reduce the electric energy charges from the electric utility fails to address 50% of the total electric energy charges.

### BRIEF DESCRIPTION OF THE DRAWINGS/FIGURES

Embodiments of the present disclosure are described with reference to the accompanying drawings. In the drawings, like reference numerals indicate identical or functionally similar elements. Additionally, the left most digit(s) of a reference number typically identifies the drawing in which the reference number first appears.

FIG. 1 illustrates a block diagram of a building automation system such that a controller may automatically adjust the energy consumption of different loads of the building based on load parameters associated with the different loads as well as the consumption of renewable energy from renewable energy sources associated with the building to decrease the electric utility demand of the building relative to the electric utility; and

FIG. 2 illustrates a block diagram of building automation configuration where the controller monitors various load parameters associated with the current electric utility demand of the building required to maintain the building below the electric utility demand threshold based on the energy consumption of the building to ensure the peak demand of the building is maintained below the electric utility demand threshold.

### DETAILED DESCRIPTION OF THE PRESENT DISCLOSURE

The following Detailed Description refers to accompanying drawings to illustrate exemplary embodiments consistent with the present disclosure. References in the Detailed Description to “one exemplary embodiment,” an “exemplary embodiment,” an “example exemplary embodiment,” etc., indicate the exemplary embodiment described may include a particular feature, structure, or characteristic, but every exemplary embodiment may not necessarily include the particular feature, structure, or characteristic. Moreover, such phrases are not necessarily referring to the same exemplary embodiment. Further, when a particular feature, structure, or characteristic may be described in connection with an exemplary embodiment, it is within the knowledge of those skilled in the art(s) to effect such feature, structure, or characteristic in connection with other exemplary embodiments whether or not explicitly described.

The exemplary embodiments described herein are provided for illustrative purposes, and are not limiting. Other exemplary embodiments are possible, and modifications may be made to the exemplary embodiments within the spirit and scope of the present disclosure. Therefore, the Detailed Description is not meant to limit the present disclosure. Rather, the scope of the present disclosure is defined only in accordance with the following claims and their equivalents.

Embodiments of the present disclosure may be implemented in hardware, firmware, software, or any combination thereof. Embodiments of the present disclosure may also be implemented as instructions applied by a machine-readable medium, which may be read and executed by one or more processors. A machine-readable medium may include any mechanism for storing or transmitting information in a form readable by a machine (e.g., a computing device). For example, a machine-readable medium may include read only memory (“ROM”), random access memory (“RAM”), magnetic disk storage media, optical storage media, flash memory devices, electrical optical, acoustical or other forms of propagated signals (e.g., carrier waves, infrared signals, digital signals, etc.), and others. Further firmware, software routines, and instructions may be described herein as performing certain actions. However, it should be appreciated that such descriptions are merely for convenience and that such actions in fact result from computing devices, processors, controllers, or other devices executing the firmware, software, routines, instructions, etc.

For purposes of this discussion, each of the various components discussed may be considered a module, and the term “module” shall be understood to include at least one software, firmware, and hardware (such as one or more circuit, microchip, or device, or any combination thereof), and any combination thereof. In addition, it will be understood that each module may include one, or more than one, component within an actual device, and each component that forms a part of the described module may function either cooperatively or independently from any other component forming a part of the module. Conversely, multiple modules described herein may represent a single component within an actual device. Further, components within a module may be in a single device or distributed among multiple devices in a wired or wireless manner.

The following Detailed Description of the exemplary embodiments will so fully reveal the general nature of the present disclosure that others can, by applying knowledge of those skilled in the relevant art(s), readily modify and/or adapt for various applications such exemplary embodiments, without undue experimentation, without departing from the spirit and scope of the present disclosure. Therefore, such adaptations and modifications are intended to be within the meaning and plurality of equivalents of the exemplary embodiments based upon the teaching and guidance presented herein. It is to be understood that the phraseology or terminology herein for the purpose of description and not of limitation, such that the terminology or phraseology of the present specification is to be interpreted by those skilled in the relevant art(s) in light of the teachings herein.

### System Overview

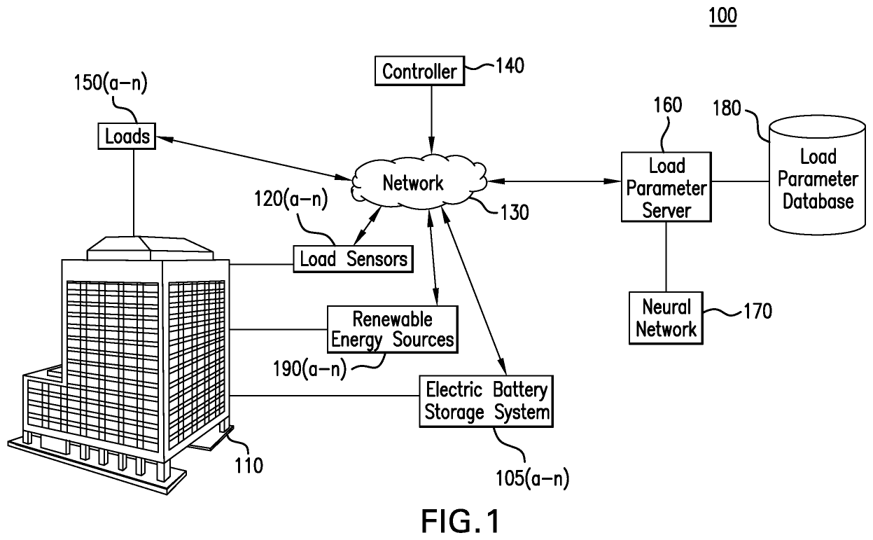

FIG. 1 illustrates a block diagram of a building automation system such that a controller may automatically adjust the energy consumption of different loads of the building based on load parameters associated with the different loads as well as the consumption of renewable energy from renewable energy sources associated with the building to decrease the electric utility demand of the building relative to the electric utility. A building automation configuration 100, includes a building 110. The building 110 includes load sensors 120(a-n), where n is an integer greater than one, renewable energy sources 190(a-n), where n is an integer equal to or greater than one, and an electric battery storage system 105(a-n), where n is an integer equal to or greater than one.

A controller 140 may automatically adjust the different loads 150(a-n), where n is an integer greater than one, of the building 110 as well as the consumption of renewable energy from the renewable energy sources 190(a-n) and the electric battery storage system 105(a-n) to maintain the electric utility demand of the building 110 below an electric utility demand threshold to decrease the amount of electric utility demand that the electric utility bills the building 110. A load parameter server 160 may gather data with regard to how the controller 140 automatically adjusts the loads 150(a-n) and renewable energy sources 190(a-n) as well as the electric battery storage system 105(a-n) based on the numerous different load parameters measured by the load sensors 120(a-n) and store such data in the load parameter database 180 to incorporate into a neural network 170.

An electric utility bills the building 110 based on the energy consumed by the building 110 over a fixed period of time that the bill covers, such as the past 30 days. Typically, the electric utility bills the building 110 for the kW/h of energy consumed by the building 110 over the 30 day time period. However, the electric utility also bills the building 110 for the electric utility demand in of the building 110. The electric utility determines the electric utility demand of the building 110 which is the peak demand of energy consumption by the building 110 for a period of time. The peak demand is the maximum amount of energy that may be consumed by the building 110 during a specified period of time by the electric utility, such as a year. Regardless of the quantity of times in a 12 month period that the building 110 actually consumes the peak demand of energy, the electric utility must provide the peak demand of energy 110 to the building 110 to ensure that the building 110 does not brown out once the building 110 does reach peak demand.

The building 110 may only reach the peak demand a few times over a 12 month period. However, the electric utility maintains the peak demand available to the building 110 throughout the 12 month period as the electric utility does not determine when and how many times the building 110 may reach peak demand. Thus, the electric utility bills the building 110 for the electric utility demand that the electric utility provides to the building 110 continuously throughout the 12 month period. Regardless as to whether the building 110 reaches peak demand one time during a 12 month period or 200 hundred times over a 12 month period, the electric utility provides the electric utility demand to the building 110 and thereby bills the building 110 for providing that electric utility demand to the building 110. For example, the building 110 may reach peak demand of 100 kW only five times over a 12 month period. However, the electric utility provides the electric utility demand of 100 kW to the building 110 to ensure that the building 110 does not brown out any time throughout a 12 month period should the building 110 happen to reach the peak demand of 100 kW. Regardless as to the building 110 only reaching peak demand of 100 kW per 12 month period, the electric utility bills the building each month for providing the electric utility demand of 100 kW to the building 110 each month. Thus, in addition to the billing the building 110 for the energy consumed in kW/h each month, the electric utility also bills the building 110 for the electric utility demand of 100 kW provided to the building 110 each month to ensure that the building 110 does not brown out any time throughout the month.

Conventional approaches to reducing the electric utility bill provided to the building 110 by the electric utility focus on the reduction of energy consumption by the building 110 in kW/h. The reduction of the amount of energy actually consumed by the building 110 each month does impact the amount of the electric utility bill in that the amount of energy consumption in kW/h billed to the building 110 by the electric utility is less when the building 110 consumes less energy in kW/h each month. However, the building 110 is a commercial building and there is still a significant requirement to consume energy to simply maintain the day to day operations of the building 110 each day and to maintain the day to day activities of the occupants of the building 110 each day. So, there is still a minimum amount of energy consumed by the building 110 each month that is required to simply maintain the day to day operations of the building 110 as well as the day to day activities of the occupants of the building 110.

Further, any reduction in the energy consumption in kW/h of the building 110 on a monthly basis in conventional approaches, fails to reduce the electric utility demand in kW that is billed to the building 110 each month. Regardless as to the decrease in energy consumption in kW/h of the building 110 each month, the electric utility continues to maintain the electric utility demand in kW provided to the building 110 as long as the building 110 continues to reach the peak demand over a 12 month period. As a result, the electric utility continues to provide the electric utility demand in kW to the building 110 to ensure that the building 110 does not brown out should the building 110 reach peak demand only one time over a 12 month period. In doing so, the electric utility continues to bill the building 110 for the electric utility demand in kW each month regardless as to how much the building 110 has decreased the amount of energy consumed in kW/h that month as long as the building 110 continues to reach the peak demand at least once over a 12 month period. Regardless, as to how much the building 110 reduces the amount of energy consumed each month in kW/h by conventional approaches, the electric utility demand of the building 110 is maintained thereby triggering the electric utility to continue to bill the building 110 for the electric utility demand despite any decrease in the amount of energy consumed by the building 110.

Rather than simply addressing the reduction of energy consumption in kW/h of the building 110 to reduce the bill allocated by the electric utility to the building 110, the controller 140 may automatically adjust the different loads of the building 110 to ensure that the electric utility demand of the building 110 is maintained within an electric utility demand threshold. The electric utility demand threshold is the peak demand determined for the building 110 to ensure that the electric utility demand provided by the electric utility to the building 110 is capped at the electric utility demand threshold thereby also capping what the electric utility charges to the building 110 for the electric utility demand. In ensuring that the electric utility demand threshold is not exceeded based the operation of the loads of the building 110 at any time such that the peak demand of the building 110 satisfies the electric utility demand threshold, the controller 140 may impact what the electric utility bills the building 110 for electric utility demand in kW in addition to the amount of energy consumed by the building 110 in kW/h.

A building automation system automatically adjusts a plurality of loads 150(a-n) associated with the a building 110 based on a plurality of load parameters that are monitored throughout the building 110. A plurality of load sensors 120(a-n) are positioned in the building 110 and each load monitoring sensor 120(a-n) may measure a corresponding load parameter associated with each corresponding load of the building 110. Each load parameter is indicative as to a current electric utility demand of the building 110 based on current energy consumption of the loads associated with the building 110. A controller 140 may monitor each load parameter measured by each corresponding load monitoring sensor 120(a-n) to determine whether at least one load parameter deviates beyond at least one corresponding load parameter threshold. The controller 140 may activate at least one graduated action when each load parameter deviates beyond the at least one corresponding load parameter threshold to automatically adjust the current energy consumption of the corresponding load that is deviated beyond the at least one corresponding load parameter threshold to maintain the current electric utility demand within an electric utility demand threshold. The electric utility demand threshold is a peak demand allocated to the building 110 by an electric utility to ensure that the peak demand for energy consumption of the building 110 is satisfied.

The controller 140 may automatically adjust the loads 150(a-n) of the building 110 to ensure that the energy consumption of the loads 150(a-n) when operating maintains the current electric utility demand below the electric utility demand threshold. The current electric utility demand is the current energy consumption of the building 110 relative to the determined peak demand of the building 110 which is identified as the electric utility demand threshold. As the loads 150(a-n) of the building 110 consume energy, the current electric utility demand is the current energy consumption of the building 110. However, the controller 140 may automatically adjust the loads 150(a-n) to ensure that the current electric utility demand remains below the electric utility demand threshold. The electric utility demand threshold is the peak demand determined by the operator of the building 110 that the current electric utility demand of the building 110 is to not exceeded.

The controller 140 in automatically adjusting the loads 150(a-n) of the building 110 to maintain the current electric utility demand below the electric utility demand threshold ensures that the peak demand of the building 110 as determined by the operator of the building 110 is not exceeded. In doing so, the electric utility demand provided by the electric utility to the building 110 remains below the electric utility demand threshold as determined by the operator of the building 110. Thus, the electric utility demand billed by the electric utility to the building 110 remains capped at the electric utility demand threshold as determined by the operator of the building 110 thereby ensuring that the building 110 is not billed for additional electric utility demand that exceeds the electric utility demand threshold.

The current electric utility demand of the building 110 is represented based on the different load parameters measured by the load sensors 120(a-n) in real-time. As each of the different load parameters indicate that adjustment of the operation of the loads 150(a-n) is required to ensure that the current electric utility demand of the building 110 remains below the electric utility demand threshold, such current electric utility demand of the building 110 based on the current energy consumption of the loads 150(a-n) indicates that adjustment of the loads 150(a-n) by the controller 140 is needed to ensure that the current electric utility demand of the building 110 remains below the electric utility demand threshold. In doing so, the controller 140 only activates graduated actions relative to the operation of the loads 150(a-n) to ensure that the currently electric utility demand remains below the electric utility demand threshold and then ceases the execution of the graduated actions when such graduated actions are no longer necessary to maintain the current electric utility demand of the building 110 below the electric utility demand threshold. In doing so, occupants of the building 110 may continue to benefit from the operation of the loads 150(a-n) but in doing so may only be negatively impacted by decreasing the operation of the loads 150(a-n) when necessary to maintain the current electric utility demand of the building 110 below the electric utility demand threshold.

The loads 150(a-n) of the building 110 are systems and/or services associated with the building 110 that when executed provide benefits to the occupants of the building 110 and/or to the building 110 itself but in doing so consumes energy that impacts the current electric utility demand of the building 110. For example, electric vehicle chargers associated with the building 110 are loads 150(a-n) of the building 110 in that the electric vehicle chargers provide a benefit to the occupants of the building 110 in that those occupants that drive electric vehicles to the building 110 are able to charge their electric vehicles when occupying the building 110. However, such electric vehicle chargers when operational and charging cars, consume energy that increases the overall electric utility demand of the building 110 when the electric vehicle chargers are operational. Examples of loads 150(a-n) of the building 110 may include but are not limited to electrical vehicle chargers, information technology (IT) services for the building 110 such as building security, internet, phone and so on, HVAC for the IT equipment in the IT room that provides the IT services, outlets that provide energy for computers, laptops, and so on to maintain productivity of the occupants of the building 110, refrigerator for food, other appliances, HVAC for occupant comfort, hot water for occupant comfort, internal lights and/or external lights for occupant comfort, and/or any other load 150(a-n) that when executed consumes energy to provide benefits to the occupants of the building and/or the building 110 itself that will be apparent to those skilled in the relevant art(s) without departing from the spirit and scope of the disclosure.

In doing so, each load 150(a-n) of the building 110 may have a corresponding load sensor 120(a-n) that measures a corresponding load parameter that is associated with each corresponding load 150(a-n) of the building 110 in real-time. For example, the IT sensor measures the energy consumed by the IT equipment in real-time, the HVAC IT sensor measures the energy consumed by the HVAC that cools the IT equipment in real-time, the outlet sensors measure the energy consumed by computers, laptops and so on that are plugged into the outlets in real-time, the refrigeration sensor measures the energy consumed by the refrigerators in real-time, the appliance sensors measure the energy consumed by the appliances in real-time, the HVAC occupant sensor measures the energy consumed by the HVAC for occupant comfort in real-time, the hot water sensor measures the energy consumed to generate hot water in real-time, the lights sensors measure the energy consumed by the lights in real-time, the electric vehicle charger sensors measure the energy consumed by the electric vehicle chargers in real-time and so on.

Rather than simply maintaining the operation of the loads 150(a-n) as the building 110 and/or the occupants of the building 110 desire such that the current electric utility demand may increase above the electric utility demand threshold at any time unchecked, the controller 140 may automatically adjust the loads 150(a-n) to address each load parameter when each load parameter deviates from the load parameter threshold in real-time. In doing so, the controller 140 may automatically adjust each respective load 150(a-n) based on the load sensors 120(a-n) that are each measuring the load parameters. The controller 140 may then address each load parameter that deviates from the corresponding load parameter threshold as needed thereby maintaining the current electric utility demand of the building 110 below the electric utility demand threshold but in doing so only limits the operation of each load 150(a-n) as needed to maintain the current electric utility demand below the electric utility demand threshold.

For example, rather than automatically deactivating the HVAC for comfort of the occupants, the hot water for comfort of the occupants, the indoor and/or outdoor lighting for comfort of the occupants, and the electric vehicle chargers, the controller 140 may temporarily deactivate the electric vehicle chargers as well as dimming the indoor lighting and deactivating the outdoor lighting. In doing so, the controller 140 may maintain the activation of the HVAC for comfort of the occupants as well as the hot water for the comfort of the occupants as those loads 150(a-n) have a greater impact on the comfort of the occupants. As a result, the controller 140 may prevent the automatic deactivation of the HVAC for comfort of the occupants as well as the hot water for the comfort of the occupants while still maintaining the current electric utility demand of the building 110 below the electric utility demand threshold. Thus, the negative impact to the benefit of the occupants is limited to the temporary charging of electric vehicles as well as the dimming of indoor lighting and deactivating of the outdoor lighting to maintain the current electric utility demand below the electric utility demand threshold such that the unnecessary deactivation of the of the HVAC and hot water for occupant comfort is prevented.

Each load parameter may be indicative as to the current electric utility demand of the building 110 based on current energy consumption of the loads 150(a-n) of the building 110. Each load parameter may provide insight as to the energy demand of the occupants of the building 110 as well as the building 110 itself in real-time that thereby indicates whether the operation of the loads 150(a-n) of the building 110 is to be adjusted accordingly by the controller 140 based on the different load parameters. For example, the electric vehicle charger sensors associated with each electric vehicle charger identify that each electric vehicle charger is currently charging a corresponding electric vehicle. As the electric vehicle charger parameter increases, such an increase is indicative that the current electric utility demand of the building 110 is also increasing and approaching the electric utility demand threshold based on the activity of the occupants of the building 110 in real-time. The controller 140 may then deactivate each electric vehicle charger in real-time to accommodate the increase in the current electric utility demand of the building to maintain below the electric utility demand threshold. The load sensors 120(a-n) may correspond to each load 150(a-n) and may be capable of measuring the energy consumption of the corresponding load 150(a-n) in real-time. The load parameter measured by the load sensors 120(a-n) may be the any type of parameter that corresponds to the load 150(a-n) that is consuming energy and impacting the current electric utility demand of the building 110.

As noted above, the controller 140 may monitor each load parameter measured by each corresponding load sensor 120(a-n) to determine whether at least one load parameter deviates beyond the at least one corresponding load parameter threshold. Each corresponding load parameter threshold is the threshold for each load parameter that when deviated is indicative that the current electric utility demand of the building 110 is increasing towards the electric utility demand threshold and requires an automatic adjustment in the operation of the loads 150(a-n) as instructed by the controller 140 to accommodate the load parameter that has deviated from the corresponding load parameter threshold. For example, the load parameter for the external lights for comfort of the occupants may have a corresponding load parameter threshold that when the load parameter for the external lights increases above the load parameter threshold for the external lights is indicative that the energy consumed by the outdoor lights for occupant comfort has increased to a level may be automatically decreased by the controller 140 to maintain the current electric utility demand of the building below the electric utility demand threshold. In doing so, the controller 140 automatically addresses the current electric utility demand of the building 110 to maintain below the electric utility demand threshold but does so by selectively impacting how the occupants are negatively impacted by the decreasing the energy consumed by the outdoor lights while maintaining the operation of other loads 150(a-n) that have a greater benefit to the comfort of the occupants.

As noted above, the controller 140 may activate at least one graduated action when each load parameter deviates beyond the at least one corresponding load parameter threshold to automatically adjust the current energy consumption of the corresponding load 150(a-n) that is deviated beyond the at least one corresponding load parameter threshold to maintain the current electric utility demand within an electric utility demand threshold. The electric utility demand threshold is a peak demand allocated to the building 110 by an electric utility to ensure that the peak demand for energy consumption of the building 110 is satisfied. Each graduated action activated by the controller 140 may be an action executed by the corresponding loads 150(a-n) to address the load parameter that has deviated from the load parameter threshold. For example, the graduated action may be dimming the indoor lighting for occupant comfort to decrease the load parameter of energy consumed by the indoor lighting to below the load parameter threshold for the indoor lighting to maintain the current electric utility demand of the building 110 below the electric utility demand threshold.

As noted above, the loads 150(a-n) may include but are not limited to electrical vehicle chargers, information technology (IT) services for the building 110 such as building security, internet, phone and so on, HVAC for the IT equipment in the IT room that provides the IT services, outlets that provide energy for computers, laptops, and so on to maintain productivity of the occupants of the building 110, refrigerator for food, other appliances, HVAC for occupant comfort, hot water for occupant comfort, internal lights and/or external lights for occupant comfort, and/or any other load 150(a-n) that when executed consumes energy to provide benefits to the occupants of the building and/or the building 110 itself that will be apparent to those skilled in the relevant art(s) without departing from the spirit and scope of the disclosure. The graduated actions activated by the controller 140 may include any type of action executed by the corresponding loads 150(a-n) to decrease and/or increase the energy consumption of the corresponding loads 150(a-n) to maintain the current electric utility demand of the building 110 below the electric utility demand threshold while limiting the impact on the comfort of the occupants of the building 110 and the execution of day to day operations of the building 110 and the occupants of the building 110 that will be apparent to those skilled in the relevant art(s) without departing from the spirit and scope of the disclosure.

As the controller 140 automatically adjusts the loads 150(a-n) to execute graduated actions to address each load parameter that deviates from the corresponding load parameter threshold in real-time, the current electric utility demand of the building 110 is maintained within the electric utility demand threshold due to the customized adjustment of the loads 150(a-n) to execute the graduated actions necessary to address each load parameter that deviates from the corresponding load parameter threshold as each load parameter deviates from the corresponding load parameter threshold in real-time. In doing so, the controller 140 is able to maintain the current electric utility demand of the building 110 within the electric utility demand threshold but does so by limiting the graduated actions executed by the loads 150(a-n) to those graduated actions to maintain the current electric utility demand below the electric utility demand threshold. The controller 140 also limits the duration of such graduated actions to the duration necessary to maintain the load parameters within their corresponding load parameter thresholds. Thus, the current electric utility demand of the building 110 is maintained within the electric utility demand threshold but does so without unnecessary decrease of energy consumption by loads 150(a-n). Real-time is the state of the load parameters as monitored by the controller 140 as the loads 150(a-n) operate and then the execution of graduated actions to address the load parameters that deviate from the corresponding load parameter thresholds to maintain the current electric utility demand of the building 110 within the electric utility demand threshold.

In addition to the loads 150(a-n), the controller 140 may also automatically adjust the consumption of renewable energy as stored by the corresponding renewable energy sources 190(a-n) associated with the building 110 to further assist in maintaining the current electric utility demand below the electric utility demand threshold. At least one renewable energy source 190(a-n) is associated with the building 110 and may provide renewable energy to the building 110. The renewable energy provided by the at least one renewable energy source 190(a-n) does not impact an increase in the electric utility demand of the building 110 as the renewable energy is not provided by the electric utility. The building 110 may have different renewable energy sources 190(a-n) associated with the building 110 in that each of the renewable energy sources 190(a-n) may provide renewable energy that is available to the building 110 for different loads 150(a-n) to consume. However, the renewable energy provided by the renewable energy sources 190(a-n) may have no impact on the current electric utility demand of the building 110 as the renewable energy consumed by the building 110 as provided by the renewable energy sources 190(a-n) is not energy provided by the electric utility but rather renewable energy captured and/or generated by the renewable energy sources 190(a-n).

The controller 140 may then monitor an amount of renewable energy that is available from the at least one renewable energy resource 150(a-n) to power the plurality of loads 150(a-n) associated with the building 110. The controller 140 may then activate at least one graduated action to provide the renewable energy available from the at least one renewable energy resource 190(a-n) to each load 150(a-n) based on each corresponding load parameter for each load 150(a-n) to provide the renewable energy to each corresponding load 150(a-n) when the renewable energy is available to prevent accessing energy from the electric utility when the renewable energy is available. Rather than simply automatically adjusting the operation of the loads 150(a-n) to decrease the energy consumption of the loads to maintain the current electric utility demand below the electric utility demand threshold, the controller 140 may first maintain the load parameters of the loads 150(a-n) within the load parameter thresholds by providing the renewable energy stored in the renewable energy sources 190(a-n) to the loads 150(a-n).

In doing so, the controller 140 may refrain from negatively impacting the comfort of the occupants of the building 110 and/or the day to day operations of the building 110 and/or the occupants of the building 110 by first providing renewable energy for the loads 150(a-n) to consume before adjusting the operation of the loads 150(a-n) to maintain the electric utility demand of the building 110 within the electric utility demand threshold. The renewable energy sources 190(a-n) associated with the building 110 may include but are not limited to a solar photovoltaic (PV) system, an air-source heat pump, a phase change material (PCM) system, a thermal energy storage system, water energy storage systems, ice-making systems, and/or any other type of renewable energy source 190(a-n) will be apparent from those skilled in the relevant art(s) without departing from the spirit and scope of the present disclosure. These examples are illustrative and not intended to limit the present disclosure.

In addition to the loads 150(a-n), the controller 140 may also automatically adjust the consumption of electric energy as stored by an electric battery storage system 105(a-n) associated with the building 110 to further assist in maintaining the current electric utility demand below the electric utility demand threshold. An electric battery storage system 105(a-n) is associated with the building 110 and may store electric energy available to the building 110. The controller 140 may monitor an amount of electric energy that is stored in the electric battery storage system 105(a-n) to power the plurality of loads 150(a-n) associated with the building 110. The controller 140 may then activate at least one graduated action to provide the stored electric energy available from the electric battery storage system 105(a-n) to each load 150(a-n) based on each corresponding load parameter for each load 150(a-n) to provide the stored electric energy to each corresponding load 150(a-n) when the stored electric energy is available to prevent accessing energy from the electric utility when the stored electric energy is available.

Rather than simply automatically adjusting the operation of the loads 150(a-n) to decrease the energy consumption of the loads 150(a-n) to maintain the electric utility demand below the electric utility demand threshold, the controller 140 may first maintain the load parameters of the loads 150(a-n) within the load parameter thresholds by providing the electric energy stored in the electric battery storage system 105(a-n) to the loads 150(a-n). In doing so, the controller 140 may refrain from negatively impacting the comfort of the occupants of the building 110 and/or the day to day operations of the building 110 and/or the day to day operations of the occupants of the building 110 by first providing the stored electric energy for the loads 150(a-n) to consume before adjusting the operation of the loads 150(a-n) to maintain the electric utility demand of the building 110 within the electric utility demand threshold. The electric battery storage system 105(a-n) may include but not limited to lithium ion batteries and/or any other electric battery storage system that may store electric energy for the building 110 that does not impact the current electric utility demand of the building 110 that will be apparent from those skilled in the relevant art(s) without departing from the spirit and scope of the present disclosure. These examples are illustrative and not intended to limit the present disclosure.

The streaming of the load parameters as measured by the load sensors 120(a-n) in real-time may be wirelessly streamed to the controller 140 via network 130 such that the controller 140 may monitor the load parameters as measured by the load sensors 120(a-n) wirelessly in real-time. Further, the controller 140 may then activate the appropriate graduated actions to be executed by the loads 150(a-n) and/or deactivated based on wireless communication via network 130 in real-time as the load parameters deviate from the corresponding load parameter thresholds and/or are maintained within the corresponding load parameter thresholds.

Communication between the load sensors 120(a-n), the controller 140, loads 150(a-n), the renewable energy sources 190(a-n), the electric battery storage system 105(a-n) and/or the air quality parameter server 160, may occur via wireless and/or wired connection communication. Wireless communication may occur via one or more networks 130 such as the internet or Wi-Fi wireless access points (WAP). In some embodiments, the network 130 may include one or more wide area networks (WAN) or local area networks (LAN). The network may utilize one or more network technologies such as Ethernet, Fast Ethernet, Gigabit Ethernet, virtual private network (VPN), remote VPN access, a variant of IEEE 802.11 standard such as Wi-Fi, and the like. Communication over the network 130 takes place using one or more network communication protocols including reliable streaming protocols such as transmission control protocol (TCP), Ethernet, Modbus, CanBus, EtherCAT, ProfiNET, BacNET, and/or any other type of network communication protocol that will be apparent from those skilled in the relevant art(s) without departing from the spirit and scope of the present disclosure. Wired connection communication may occur but is not limited to a fiber optic connection, a coaxial cable connection, a copper cable connection, and/or any other type of direct wired connection that will be apparent from those skilled in the relevant art(s) without departing from the spirit and scope of the present disclosure. These examples are illustrative and not intended to limit the present disclosure.

### Parameter Monitoring and Control

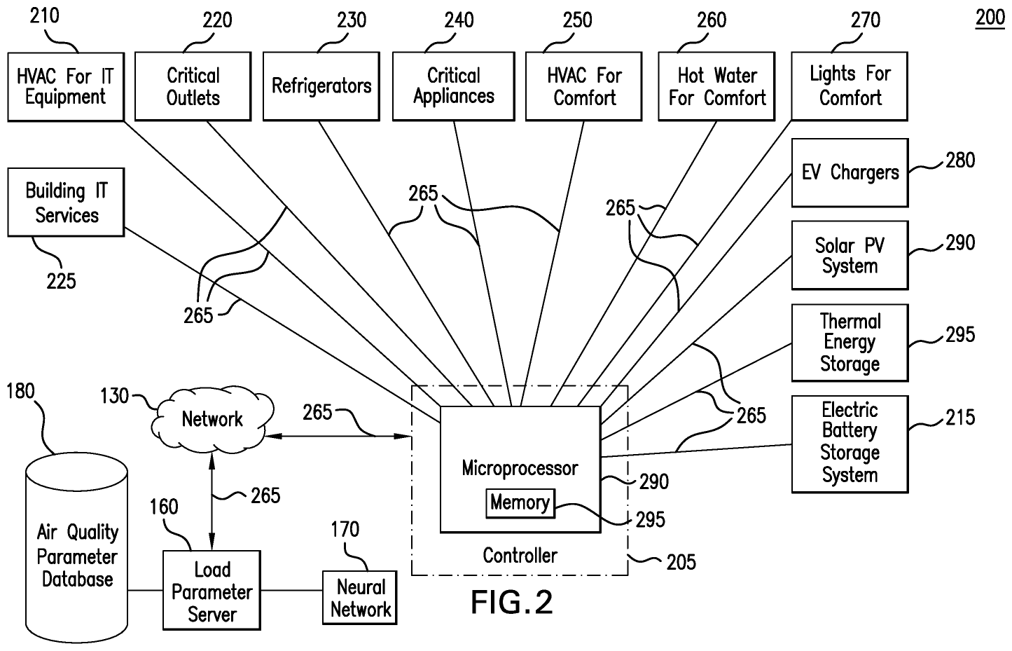

FIG. 2 illustrates a block diagram of building automation configuration 200 where the controller 205 monitors various load parameters associated with the current electric utility demand of the building 110 required to maintain the building 110 below the electric utility demand threshold based on the energy consumption of the building to ensure the peak demand of the building 110 is maintained below the electric utility demand threshold. The controller 205 may then automatically activate graduated actions to be executed by the different loads 150(a-n) in response to the monitored load parameters. In doing so, the controller 205 may continuously monitor the load parameters and activate the graduated actions to be executed by the different loads 150(a-n) in real-time when necessary to maintain the load parameters within their corresponding load parameter thresholds to maintain the current electric utility demand of the building 110 within the electric utility demand threshold. The building automation configuration 200 shares many similar features with the building automation configuration 100; therefore, only the differences between the building automation configuration 200 and the building automation configuration 100 are to be discussed in further details.

In one embodiment of the present disclosure, the controller 205 may connect and/or communicate with via wireless communication 265 to one or more modules that when commands are received by the controller 205 a graduated action is activated based on the monitoring of load parameters of different sensors to maintain the load parameters within the corresponding load parameter thresholds to maintain the current electric utility demand of the building 110 within the electric utility demand threshold of the building automation configuration 200. The one or more modules of the building IT services 225, the HVAC for IT equipment 210, the critical outlets 220, the refrigerators 230, the critical appliances 240, the HVAC for comfort 250, the hot water for comfort 260, the lights for comfort 270, the EV chargers 280, the solar PV system 290, the thermal energy storage 295, the electric battery storage system 215, and/or any other module that may be controlled by the controller 205 to ensure the current electric utility demand of the building 110 is maintained below the electric utility demand threshold that will be apparent to those skilled in the relevant art(s) without departing from the spirit and scope of the disclosure.

The controller 205 includes a microprocessor 290 and a memory 295 and may be referred to as a computing device or simply “computer”. For example, the controller 205 may be workstation, mobile device, computer, cluster of computers, remote cloud service, set-top box, or other computing device. In one embodiment of the present invention, multiple modules may be implemented on the same computing device. Such a computing device may include software, firmware, hardware, or a combination thereof. Software may include one or more applications on an operating system. Hardware can include, but is not to be limited to, the microprocessor 290 and/or the memory 295. The controller 205 may be in wireless communication with each of the building IT services 225, the HVAC for IT equipment 210, the critical outlets 220, the refrigerators 230, the critical appliances 240, the HVAC for comfort 250, the hot water for comfort 260, the lights for comfort 270, the EV chargers 280, the solar PV system 290, the thermal energy storage 295, and the electric battery storage system 215.

A plurality of critical load monitoring sensors may be positioned in the building 110 and each critical load monitoring sensor may measure a corresponding critical load parameter associated with each corresponding critical load of the building 110. Each critical load parameter is indicative as to an impact on the current electric utility demand by each critical load based on current energy consumption of the critical loads associated with the building 110. The controller 205 may then monitor each critical load parameter measured by each corresponding critical load monitoring sensor to determine whether at least one critical load parameter deviates beyond at least one corresponding critical load parameter threshold. Each critical load is a load associated with the building 110 that cannot be deactivated to eliminate energy consumption by the critical load.

The controller 205 may then activate at least one graduated action when each critical load parameter deviates beyond the at least one corresponding critical load parameter threshold to automatically adjust the current energy consumption of the corresponding critical load that is deviated beyond the at least one corresponding critical load parameter threshold without deactivating the corresponding critical load. The activation of the at least one graduated action maintains the current electric utility demand within the electric utility demand threshold. The critical loads of the building 110 include loads that are essential to the day to day operations of the building 110 and to the day to day activities of the occupants of the building 110 in that deactivating the energy consumption of those critical loads of the building 110 to simply maintain the electric utility demand of the building 110 within the electric utility demand threshold may be difficult for the building 110 to endure.

The controller 205 may automatically adjust the operation of the critical loads to maintain the critical load parameter associated with each critical load within the corresponding critical load parameter threshold. However, such critical load parameter threshold may be determined such that any adjustment of the operation of the critical loads in decreasing the energy consumption of the critical loads does not impact the day to day operations of the building 110 and the day to day activities of the occupants of the building 110. As a result, the critical load parameter thresholds may not allow significant deviation in the critical load parameters to prevent any decrease in energy consumption of the critical loads that may adversely impact the day to day operations of the building 110 and the day to day activities of the occupants of the building 110. Thus, critical loads of the building 110 are identified as loads that the operation and/or energy consumption is to be maintained for those critical loads to continue to the service the building 110 and/or the occupants of the building. The controller 205 may refrain from deactivating any critical load and/or may refrain activating any graduated action to maintain the current electric utility demand of the building 110 that may negatively impact the day to day operations of the building 110 and the day to day activities of the occupants of the building 110.

For example, the loads associated with the building 110 that may be identified as critical loads may include the building IT services 225. The IT services 225 of the building 110 are essential to the day to day operations of the occupants of the building 110 and maintaining the business that is conducted in the building 110. The controller 205 may execute graduated actions to automatically adjust the IT services 225 to maintain the load parameter associated with the IT services 225 within the corresponding load parameter threshold. However, in doing so, the controller 205 may ensure that any adjustment refrains from significantly decreasing the energy consumption of the building IT services 225 to negatively impact the day to day operations of the building 110 and the day to day activities of the occupants of the building 110.

In another example, the loads associated with the building 110 that may be identified as critical loads may include the HVAC for IT equipment 210. The HVAC for IT equipment 210 of the building 110 are essential to the day to day operations of the occupants of the building 110 and maintaining the business that is conducted in the building 110. The controller 205 may execute graduated actions to automatically adjust the HVAC for IT equipment 210 to maintain the load parameter associated with the HVAC for IT equipment 210 within the corresponding load parameter threshold. However, in doing so, the controller 205 may ensure that any adjustment refrains from significantly decreasing the energy consumption of the HVAC for IT equipment 210 to negatively impact the day to day operations of the building 110 and the day to day activities of the occupants of the building 110.

In another example, the loads associated with the building 110 that may be identified as critical loads may include the critical outlets 220. The critical outlets 220 may be electrical outlets that provide electric energy to devices that are required by the occupants of the building 110 to maintain their day to day activities. For example, the critical outlets 220 may be known electrical outlets that provide electric energy to computers, laptops, and/or any other electronic device required to maintain the productivity of the occupants of the building 110. The controller 205 may execute graduated actions to automatically adjust the electric energy provided by the critical outlets 220 to maintain the load parameter associated with the critical outlets 220 within the corresponding load parameter threshold. However, in doing so, the controller 205 may ensure that any adjustment refrains from significantly decreasing the energy consumption of the computers, laptops, and/or other electronic devices to negatively impact the day to day operations of the building 110 and the day to day activities of the occupants of the building 110.

In another example, the loads associated with the building 110 that may be identified as critical loads may include the refrigerators 230. The refrigerators 230 may be required to refrigerate food and/or any other type of substance and so on that is necessary to maintain the day to day operations of the building 110. The controller 205 may execute graduated actions to automatically adjust the operation of the refrigerators 230 to maintain the load parameter associated with the refrigerators 230 within the corresponding load parameter threshold. However, in doing so, the controller 205 may ensure that any adjustment refrains from significantly decreasing the energy consumption of the refrigerators 230 to negatively impact the day to day operations of the building 110 and the day to day activities of the occupants of the building 110.

In another example, the loads associated with the building 110 that may be identified as critical loads may include the critical appliances 240. The critical appliances 240 may be required to operate continuously to maintain the day to day operations of the building 110. The controller 205 may execute graduated actions to automatically adjust the operation of the critical appliances 240 to maintain the load parameter associated with the critical appliances 240 within the corresponding load parameter threshold. However, in doing so, the controller 205 may ensure that any adjustment refrains from significantly decreasing the energy consumption of the critical appliances 240 to negatively impact the day to day operations of the building 110 and the day to day activities of the occupants of the building 110. The critical loads associated with the building 110 may include but are not limited to the building IT service 225, the HVAC for IT equipment 210, the critical outlets 220, the refrigerators 230, the critical appliances 240 any critical load that will be apparent to those skilled in the relevant art(s) without departing from the spirit and scope of the disclosure.

A plurality of non-critical load monitoring sensors may be positioned in the building 110 and each non-critical load monitoring sensor may measure a corresponding non-critical load parameter associated with each corresponding non-critical load of the building 110. Each non-critical load parameter is indicative as to the impact on the current electric utility demand be each non-critical load based on current energy consumption of the non-critical loads associated with the building 110. The controller 205 may then monitor each non-critical load parameter measured by each corresponding non-critical load monitoring sensor to determine whether at least one non-critical load parameter deviates beyond at least one corresponding non-critical load parameter threshold. Each non-critical load is associated with the building 110 that can be deactivated to eliminate energy consumption by the non-critical load.

The controller 205 may then activate at least one graduated action when each non-critical load parameter deviates beyond the at least one corresponding non-critical load parameter threshold to automatically adjust the current energy consumption of the corresponding non-critical load that is deviated beyond the at least one corresponding non-critical load parameter threshold. The activation of the at least one graduated action maintains the current electric utility demand within the electric utility demand threshold. The non-critical loads of the building 110 include loads that are not essential to the day to day operations of the building 110 and to the day to day activities of the occupants of the building 110 in that deactivating the energy consumption of those non-critical loads of the building 110 may maintain the current electric utility demand of the building 110 within the electric utility demand threshold without significantly impacting the day to day operations of the building 110 and the day to day activities of the occupants of the building 110.

The controller 205 may automatically adjust the operation of the non-critical loads to maintain the non-critical load parameter associated with each non-critical load within the corresponding non-critical load parameter threshold. However, such a non-critical load parameter threshold may be determined such that significant adjustment of the operation of the non-critical loads in decreasing the energy consumption of the non-critical loads does not impact the day to day operations of the building 110 and the day to day activities of the occupants of the building 110. As a result, the non-critical load parameter thresholds may allow significant deviation in the non-critical load parameters to enable significant decrease in energy consumption of the non-critical loads as even deactivation of the non-critical loads may not adversely impact the day to day operations of the building 110 and the day to day activities of the occupants of the building 110. Thus, non-critical loads of the building 110 are identified as loads that may have significant decrease in energy consumption and/or deactivation without negatively impacting day to day operations of the building 110 and day to day activities of the occupants of the building.

For example, the loads associated with the building 110 that may be identified as non-critical loads may include the HVAC for comfort 250. The HVAC for comfort 250 is not essential to the day to day operations of the building and the day to day activities of the occupants of the building 110 and the controller 205 may execute graduated actions to significantly decrease the energy consumption of the HVAC for comfort 250 as needed to maintain the load parameter associated with the HVAC for comfort 250 within the corresponding load parameter threshold. In another example, the loads associated with the building 110 that may be identified as non-critical loads may include the hot water for comfort 260. The hot water for comfort 260 is not essential to the day to day operations of the building and the day to day activities of the occupants of the building 110 and the controller 205 may execute graduated actions to significantly decrease the energy consumption of the hot water for comfort 260 as needed to maintain the load parameter associated with the hot water for comfort 260 within the corresponding load parameter threshold.

In another example, the loads associated with the building 110 that may be identified as non-critical loads may include the lights for comfort 270. The lights for comfort 270 is not essential to the day to day operations of the building and the day to day activities of the occupants of the building 110 and the controller 205 may execute graduated actions to significantly decrease the energy consumption of the lights for comfort 270 as needed to maintain the load parameter associated with the lights for comfort 270 within the corresponding load parameter threshold. In another example, the loads associated with the building 110 that may be identified as non-critical loads may include the EV chargers 280. The EV chargers 280 are not essential to the day to day operations of the building 110 and the day to day activities of the occupants of the building 110 and the controller 205 may execute graduated actions to significantly decrease the energy consumption of the EV chargers 280 as needed to maintain the load parameter associated with the EV chargers 280 within the corresponding load parameter threshold. The non-critical loads associated with the building 110 may include but are not limited to the HVAC for comfort 250, hot water for comfort 260, the lights for comfort 270, the EV chargers 280, and/or any other non-critical load that will be apparent to those skilled in the relevant art(s) without departing from the spirit and scope of the disclosure.

The controller 205 may prioritize each of the non-critical loads to determine a priority in deactivating each non-critical load when the current electric utility demand exceeds the electric utility demand threshold. The controller 205 may automatically deactivate a first non-critical load based on a first priority associated with the first non-critical load to deactivate the first non-critical load when the current electric utility demand exceeds the electric utility demand threshold. The controller 205 may then continue to automatically deactivate each subsequent non-critical load based on each priority in deactivating each corresponding non-critical load until the deactivation of the each subsequent non-critical load decreases the electric utility demand below the electric utility demand threshold. The controller 205 may maintain activation of each remaining non-critical load when the electric utility demand decreases below the electric utility demand threshold.

For example, the controller 205 may monitor the current electric utility demand of the building 110 and may determine that that the current electric utility demand is exceeding the electric utility demand threshold. The controller 205 may then determine the priority in deactivating each non-critical load and may determine that the hot water for comfort 260 is the first non-critical load to be deactivated. The hot water for comfort 250 is a non-critical load in that the occupants of the building 110 may continue to execute their day to day activities but with less hot water for showering, washing hands, coffee, dishwashers, and so on. The controller 205 may then continue to decrease the operation of the hot water for comfort 260 until the current electric utility demand of the building 110 decreases below the electric utility demand threshold to the point where the controller 205 may deactivate the hot water for comfort 260 to decrease the current electric demand below the electric utility demand threshold.

In such an example, the controller 205 may deactivate the hot water for comfort 260 as the current electric utility demand of the building 110 continues to remain above the electric utility demand threshold. The controller 205 may then determine the priority in deactivating the second non-critical load to be deactivated is the HVAC for comfort 250. The HVAC for comfort 250 is a non-critical load in that the occupants of the building 110 may refrain from having HVAC to execute their day to day activities. Having less HVAC for comfort 250 has more of a negative impact on the day to day activities of the occupants of the building 110 than less hot water for comfort 260 as the occupants of the building may experience more discomfort in warmer temperatures in the building 110 as compared to having less hot water available. Thus, the controller 205 may move to addressing the energy consumption of the HVAC for comfort 250 after deactivating the hot water for comfort 260. The controller 205 may then continue to decrease the operation of the HVAC for comfort 250 until the electric utility demand for the building 110 decreases below the electric utility demand threshold to the point where the controller 205 may deactivate the HVAC for comfort 250 to decrease the current demand below the electric utility demand threshold. The controller 205 may then continue to deactivate the remaining non-critical loads, such as the lights for comfort 270 and the EV chargers 280, based on priority to further decrease the current electric utility demand of the building 110 to be below the electric utility demand threshold.

As noted above, the controller 205 may monitor an amount of renewable energy that is available from renewable energy resources associated with the building 110, such as the solar PV system 290 and/or the thermal energy storage 295, to power the critical and/or non-critical loads. The controller 205 may activate different graduated actions to provide the renewable energy available from the solar PV system 290 and/or the thermal energy storage 295 to the critical and/or non-critical loads when the renewable energy is available to prevent the building 110 from accessing energy from the electric utility grid when the renewable energy is available. In doing so, the controller 205 may ensure that the critical and/or non-critical loads are provided the renewable energy that is available to be consumed by the critical and/or non-critical loads in order to further maintain the current electric utility demand of the building 110 below the electric utility demand threshold.

The controller 205 may prioritize each of the non-critical loads to determine a priority in activating each non-critical load when renewable energy is available from the at least one renewable energy resource to power each activated non-critical load associated with the building 110. The controller 205 may automatically activate a first non-critical load based on a first priority associated with the first non-critical load to activate the first non-critical load when the renewable energy is available from the at least one renewable energy resource. The controller 205 may continue to automatically activate each subsequent non-critical load based on each priority in activating each corresponding non-critical load until the activation of each subsequent non-critical load consumes the renewable energy available from the at least one renewable energy resource. The controller 205 may maintain deactivation of each remaining non-critical load that is not previously activated based on the priority of activating each non-critical load when the renewable energy is not available from the at least one renewable energy resource.

For example, the controller 205 may monitor the amount of renewable energy that is available from the solar PV system 290 and/or the thermal energy storage 295 and may determine that that there is sufficient renewable energy that is available to provide to the non-critical loads rather than electric energy from the electric utility grid to maintain the electric current demand below the electric utility demand threshold. The controller 205 may then determine the priority in activating each non-critical load and may determine that the lights for comfort 270 is the first non-critical load to be activated and powered by the renewable energy currently provided by the solar PV system 290 and/or the thermal energy storage 295. The light for comfort 270 is a non-critical load that the occupants of the building 110 may continue to execute their day to day activities but with dimmer and/or less indoor lighting and/or less outdoor lighting that is not necessary for the occupants to continue to execute their day to day activities. However, once renewable energy is available by the solar PV system 290 and/or the thermal energy storage 295, the controller 205 may then increase the operation of the lights for comfort 270 as in doing so increases the comfort of the occupants of the building 110 without increasing the current electric demand of the building 110. The controller 20 may maintain the activation of the lights for comfort 270 as long as renewable energy is available from the solar PV system 290 and/or the thermal energy storage 295.

In such an example, the controller 205 may activate the lights for comfort 270 as the renewable energy remains available from the solar PV system 290 and/or the thermal energy storage 295. The controller 205 may then determine that additional renewable energy remains available from the solar PV system 290 and/or the thermal energy storage 295 after fully activating the lights for comfort 270. The controller 205 may then determine the priority in activating the second non-critical load to be activated is EV chargers 280 so that the associated electric vehicles may travel from the building 110 to the home destination of the occupant. The EV chargers 280 are non-critical loads in that only a select quantity of occupants of the building 110 may travel to the building 110 in electric vehicles and to do so may not drain the electric battery of the electric vehicles thereby preventing the occupants from returning to their home destination from the building 110 via the electric vehicles.

Possibly unnecessary charging the electric vehicles when the electric batteries of the electric vehicles may already have sufficient electric energy to ensure the occupants return their home destination from the building 110 has less of an impact on the occupants of the building 110 as having lights for comfort 270 impacts all occupants of the building 110 rather than a select few. Thus, the controller 205 may move to activating the EV chargers 280 by providing the EV chargers 280 with the remaining renewable energy available from the solar PV system 290 and/or the thermal energy storage 295 after the lights for comfort 270 are fully activated via the renewable energy. The controller 205 may then continue to activate the remaining non-critical loads based on priority to further activate based on the remaining available renewable energy.

The controller 205 may also activate and/or deactivate the non-critical loads based on the occupied hours of the building 110 and the non-occupied hours of the building 110. For example, the controller 205 may automatically deactivate the lights for comfort 270 and/or the EV chargers 280 during the unoccupied hours of the building 110 as the lights for comfort 270 and/or the EV chargers 280 are not required during the unoccupied hours of the building 110 as there is no benefit to having the lights for comfort 270 and/or the EV chargers 280 consume unnecessary energy during non-occupied hours of the building 110. In an embodiment, the controller 205 may also reduce the operation of the HVAC for comfort 250 and/or the hot water for comfort 260 during unoccupied hours of the building 110. However in an embodiment, the controller 205 may determine the amount of renewable energy available by the solar PV system 290 and/or the thermal energy storage 295. The controller 205 may pre-emptively activate the HVAC for comfort 250 and/or the hot water for comfort 260 during the unoccupied hours to precondition the air/water for use during the occupied hours of the building 110 when the amount of renewable energy available to the building 110 during the next day of occupied hours of the building 110 is going to be limited.

As noted above, the controller 205 may monitor an amount of stored electric energy that is stored in the electric battery storage system 215 associated with the building 110 to power the critical and/or non-critical loads. The controller 205 may activate different graduated actions to provide the electric energy available from the electric battery storage system 215 to the critical and/or non-critical loads when the stored electric energy is available to prevent the building 110 from accessing energy from the electric utility grid when the stored electric energy is available. In doing so, the controller 205 may ensure that the critical and/or non-critical loads are provided the stored electric energy that is available to be consumed by the critical and/or non-critical loads in order to further maintain the current electric utility demand of the building 110 below the electric utility demand threshold.

The controller 205 may prioritize each of the non-critical loads to determine a priority in activating each non-critical load when stored electric energy is available from the electric battery storage system 215 to power each non-critical load associated with the building 110. The controller 205 may automatically activate a first non-critical load based on a first priority associated with the first non-critical load to activate the first non-critical load when the stored electric energy is available from the electric battery storage system 215. The controller 205 may continue to automatically activate each subsequent non-critical load based on each priority in activating each corresponding non-critical load until the activation of each subsequent non-critical load consumes the renewable energy available from the electric battery storage system 215. The controller 205 may maintain deactivation of each remaining non-critical load that is not previously activated based on the priority of activating each non-critical load when the stored electric energy is not available from the electric battery storage system 215.

For example, the controller 205 may monitor the amount of stored electric energy that is available from the electric battery storage system 215 and may determine that there is sufficient stored electric energy that is available to provide to the non-critical loads rather than electric energy from the electric utility grid to maintain the current electric utility demand below the electric utility demand threshold. The controller 205 may then determine the priority in activating each non-critical load and may determine that HVAC for comfort 250 is the first non-critical load to be activated and powered by the stored electric energy currently stored by the electric battery storage system 215. The HVAC for comfort 250 is a non-critical load but once stored electric energy is available by the electric battery storage device 215, the controller 205 may then increase the operation of the HVAC for comfort 250 as in doing so increases the comfort of the occupants of the building 110 without increasing the current electric demand of the building 110. The controller 205 may maintain the activation of the HVAC for comfort 250 as long as stored electric energy is available from the electric battery storage system 215.

In such an example, the controller 205 may activate the HVAC for comfort 250 as the stored electric energy remains available from the electric battery storage 215. The controller 205 may then determine that additional stored electric energy remains available from the electric battery storage system 215. The controller 205 may then determine the priority in activating the second non-critical load to be activated is the hot water for comfort 260 so that the occupants may also enjoy the comfort of hot water. Thus, the controller 205 may move to activating the hot water for comfort 260 with the remaining stored electric energy available from the electric battery storage 215 after the HVAC for comfort 260 is fully activated via the stored electric energy. The controller 205 may then continue to activate the remaining non-critical loads based on priority to further activate based on the remaining available stored electric energy.

In an embodiment, the controller 205 may also monitor the amount of electric energy that is stored in the electric battery storage system 215 to ensure that there is sufficient electric energy stored in the electric battery storage system 215 to provide adequate stored electric energy to the critical loads should the electric energy provided by the electric utility be interrupted. In doing so, the controller 205 may no longer allocate stored electric energy to operate the non-critical loads when there is no longer sufficient stored electric energy stored in the electric battery storage 215 to provide adequate stored electric energy to the critical loads should the electric energy provided by the electric utility be interrupted. Thus, the controller 205 may ensure that the critical loads always have adequate energy available to operate should the electric energy provided by the electric utility be interrupted.

As discussed in immense detail above, the controller 205 may execute graduated actions to ensure that the current electric utility demand of the building 110 is maintained below the electric utility demand threshold. In doing so, the controller 205 may also simultaneously ensure that the building 110 does not encounter net-metering and/or back feeding electric energy back to the electric utility grid. Net-metering and/or back feeding of electric energy back to the electric utility grid occurs when the building 110 actually has a surplus of electric energy available that is not required to satisfy the current electric utility demand of the building 110. The current electric utility demand of the building 110 is satisfied thereby providing an opportunity for the building 110 to back feed electric energy back to the electric utility grid.

For example, the building 110 may have an elaborate solar PV system 250 and a thermal energy storage system 295 associated with the building 110. Often times, the elaborate solar PV system 250 may capture sufficient renewable energy to satisfy the current electric utility demand of the building 110. Even then, the elaborate solar PV system 250 may have excess renewable energy that the building 110 cannot currently consume thereby enabling the building 110 to back feed the renewable energy back to the electric utility grid as electric energy. However, the electric utility grid may purchase the excess electric energy back fed from the building 110 to the electric utility grid at a wholesale rate. The building 110 may then often times may then have to receive electric energy from the electric utility grid when the elaborate solar PV system 250, thermal energy storage 295, and/or the electric battery storage system 215 may no longer have sufficient electric energy to satisfy the current electric utility demand of the building 110. The electric utility may then sell the electric energy that the building 110 then requires at the retail rate which is greater than the wholesale rate. Thus, the building 110 did not net as much in selling back the excess electric energy to the electric utility at the wholesale rate and then essentially buying back that excess electric energy when needed at the retail rate.

As a result, the controller 205 may then monitor when the amount of electric energy available to the building 110 from the solar PV system 290 exceeds the current electric utility demand of the building 110. The controller 205 may then execute graduated actions to ensure that the excess electric energy is prevented from back feeding to the electric utility grid. In doing so, the controller 205 may ensure that the excess electric energy available to the building 110 is maintained for the use of the building 110 when the current electric utility demand of the building 110 requires the excess electric energy rather than back feeding to the electric utility grid at a wholesale rate than then later buying at the retail rate when needed by the building 110 to satisfy the current electric utility demand of the building 110. For example, the controller 205 may execute the graduated action of activating the air-source heat pump and/or pre-charge the PCM of the thermal energy storage 295 and/or charge the electric battery storage system 215 with the excess electric energy when available.

The controller 205 may also determine which graduated action in storing the excess electric energy may be the most economically favorable to the building 110. For example, the controller 205 may determine whether pre-charging the PCM of the thermal energy storage 295 with the excess electrical energy is more economically feasible than storing the excess electric energy in the electric battery storage system 215. In such an example, the controller 205 may determine that investing the excess electric energy in pre-charging the PCM of the thermal energy storage 295 may have a greater long term economic impact on the energy consumption of the building 110 than storing the excess electric energy directly into the electric battery storage system 215 even if the electric battery storage system 215 has storage capacity.

Returning to FIG. 1, as the controller 140 monitors each of the load parameters measured by the load sensors 120(a-n) as well as the amount of renewable energy is available from the renewable energy sources 190(a-n) and the amount of stored electric energy stored in the electric battery storage system 150(a-n) and the graduated actions taken by the controller 140, the controller 140 may stream the load parameter data to a load parameter database 180. Load parameter data is any type of data that is associated with the load parameters of the building 110 as well as with the amount of renewable energy available from the renewable energy resources 190(a-n) as well as the amount of stored electric energy stored in the electric battery storage system 150(a-n) as well as with the adjustments to the operation of the loads 150(a-n) that the controller 150 may execute to ensure the current electric utility demand of the building 110 does not exceed the electric utility demand threshold as well as the adjustment by the controller 140 of renewable energy and stored electric energy provided to the loads as well as the actions taken by the controller 140 to ensure back feeding of excess electric energy is prevented. Thus, the load parameter data is any type of data associated with maintaining the current electric utility demand of the building 110 below the electric utility demand threshold whether positively and/or negatively that may be incorporated in the future by the controller 140 and/or any other controller associated with any other building to assist the controller 140 and/or any other controller in automatically taking the appropriate graduated actions to ensure the current electric utility demand remains below the electric utility demand threshold.

For example, the load parameter data may be generated that is associated with the graduated actions executed by the controller 140 in maintaining the current electric utility demand threshold below the electric utility demand threshold and the impact those graduated actions had in doing so. Additionally, the load parameter data may also include the impact of the four seasons on those graduated actions executed by the controller 140 regarding the current electric utility demand relative to the current electric utility demand threshold during each of the four seasons as well as the impact of the four seasons on the renewable energy captured by the renewable energy sources 190(a-n). Additionally, the load parameter day may also include the impact of weekly weather forecasts on those graduated actions executed by the controller 140 regarding the current electric utility demand relative to the current electric utility demand threshold during each weather forecast for each week as well the impact on the weekly weather forecasts on the renewable energy captured by the renewable energy sources 190(a-n).

The controller 140 as well as any other controller associated with any other building may continuously stream load parameter data to the load parameter server 160 that is stored in the load parameter database 180. In doing so, the load parameter database 180 may continuously accumulate load parameter data that is associated with automatic adjustments of many different load parameters as well as the adjustments of providing renewable energy and stored electric energy to loads by many different controllers maintaining the current electric utility demand below the electric utility demand threshold for many buildings 110. Over time as the load parameter data accumulated by the load parameter server 160 continues to increase, the neural network 170 may then apply a neural network algorithm such as but not limited to a multilayer perceptron (MLP), a restricted Boltzmann Machine (RBM), a convolution neural network (CNN), and/or any other neural network algorithm that will be apparent to those skilled in the relevant art(s) without departing from the spirit and scope of the disclosure.

Each time the load parameter data is streamed to the load parameter server 160 and stored on the air quality parameter database 180, the neural network 170 may then assist the controller 140 by providing the controller 140 with the appropriate adjustments with regard to the appropriate load parameters as well as the providing of renewable energy and stored electric energy to automatically adjust the loads and/or renewable energy sources 190(a-n) and/or electric battery storage system 105(a-n) to head off any rising of the current electric utility demand of the building 110 that may exceed the electric utility demand threshold based on the increased amount of load parameter data stored in the load parameter database 180. The neural network 170 may assist the controller 140 in learning as to the appropriate actions to execute based on the load parameters that the building 110 is experiencing as well as the renewable energy and stored electric energy available to the building 110 such that the neural network 170 may further improve the accuracy of the controller 140 in automatically adjusting the appropriate loads 150(a-n) as well as the renewable energy provided by the renewable energy sources 190(a-n) as well as the stored electric energy stored by the electric battery storage system 105(a-n) to further enhance the current electric utility demand of the building 110 in real-time. The neural network 170 may provide the controller 140 with improved upon accuracy in automatically adjust the appropriate loads 150(a-n) as well the renewable energy provided by the renewable energy sources 190(a-n) and the stored electric energy by the electric battery storage system 105(a-n) such that the neural network 170 may continue to learn upon the accumulation of load parameter data that is provided by the controller 140 and/or any other controller associated with any other building to the load parameter server 160. Thus, the current electric utility demand of the building 110 may be further enhanced.

### CONCLUSION

It is to be appreciated that the Detailed Description section, and not the Abstract section, is intended to be used to interpret the claims. The Abstract section may set forth one or more, but not all exemplary embodiments, of the present disclosure, and thus, is not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries may be defined so long as the specified functions and relationships thereof are appropriately performed.

It will be apparent to those skilled in the relevant art(s) the various changes in form and detail can be made without departing from the spirt and scope of the present disclosure. Thus the present disclosure should not be limited by any of the above-described exemplary embodiments, but should be defined only in accordance with the following claims and their equivalents.

What is claimed is:

1. A building automation system that automatically adjusts a plurality of loads associated with a building based on a plurality of load parameters that are monitored throughout the building; comprising:
a plurality of load sensors positioned in the building with each load monitoring sensor configured to measure a corresponding load parameter associated with each corresponding load of the building, wherein each load parameter is indicative as to a current electric utility demand of the building based on current energy consumption of the loads associated with the building; and
a controller configured to:
monitor each load parameter measured by each corresponding load monitoring sensor to determine whether at least one load parameter deviates beyond at least one corresponding load parameter threshold, and
activate at least one graduated action when each load parameter deviates beyond the at least one corresponding load parameter threshold to automatically adjust the current energy consumption of the corresponding load that is deviated beyond the at least one corresponding load parameter threshold to maintain the current electric utility demand within an electric utility demand threshold, wherein the electric utility demand threshold is a peak demand allocated to the building by an electric utility to ensure that the peak demand for energy consumption of the building is satisfied.

2. The building automation system of claim 1, wherein the plurality of load sensors further comprises:
a plurality of critical load sensors positioned in the building with each critical load monitoring sensor configured to measure a corresponding critical load parameter associated with each corresponding critical load of the building, wherein each critical load parameter is indicative as to an impact on the current electric utility demand by each critical load based on current energy consumption of the critical loads associated with the building; and
a plurality of non-critical load sensors positioned in the building with each non-critical load monitoring sensor configured to measure a corresponding non-critical load parameter associated with each corresponding non-critical load of the building, wherein each non-critical load parameter is indicative as to the impact on the current electric utility demand by each non-critical load based on current energy consumption of the non-critical loads associated with the building.

3. The building automation system of claim 2, wherein the controller is further configured to:
monitor each critical load parameter measured by each corresponding critical load monitoring sensor to determine whether at least one critical load parameter deviates beyond at least one corresponding critical load parameter threshold, wherein each critical load is a load associated with the building that cannot be deactivated to eliminate energy consumption by the critical load; and
activate at least one graduated action when each critical load parameter deviates beyond the at least one corresponding critical load parameter threshold to automatically adjust the current energy consumption of the corresponding critical load that is deviated beyond the at least one corresponding critical load parameter threshold without deactivating the corresponding critical load, wherein the activation of the at least one graduated action maintains the current electric utility demand within the electric utility demand threshold.

4. The building automation system of claim 2, wherein the controller is further configured to:
monitor each non-critical load parameter measured by each corresponding non-critical load monitoring sensor to determine whether at least one non-critical load parameter deviates beyond at least one corresponding non-critical load parameter threshold, wherein each non-critical load is a load associated with the building that can be deactivated to eliminate energy consumption by the non-critical load; and
activate at least one graduated action when each non-critical load parameter deviates beyond the at least one corresponding non-critical load parameter threshold to automatically adjust the current energy consumption of the corresponding non-critical load that is deviated beyond the at least one corresponding non-critical load parameter threshold, wherein the activation of the at least one graduated action maintains the current electric utility demand within the electric utility demand threshold.

5. The building automation system of claim 4, wherein the controller is further configured to:
prioritize each of the non-critical loads to determine a priority in deactivating each non-critical load when the current electric utility demand exceeds the electric utility demand threshold;
automatically deactivate a first non-critical load based on a first priority associated with the first non-critical load to deactivate the first non-critical load when the current electric utility demand exceeds the electric utility demand threshold;
continue to automatically deactivate each subsequent non-critical load based on each priority in deactivating each corresponding non-critical load until the deactivation of each subsequent non-critical load decreases the electric utility demand below the electric utility demand threshold; and
maintain activation of each remaining non-critical load that is not previously deactivated based on the priority of deactivating each non-critical load when the electric utility demand decreases below the electric utility demand threshold.

6. The building automation system of claim 5, further comprising:
at least one renewable energy source that is associated with the building and is configured to provide renewable energy to the building, wherein the renewable energy provided by the at least one renewable energy source is energy consumed by the building that does not impact an increase in the electric utility demand of the building as the renewable energy is not provided by the electric utility.

7. The building automation system of claim 6, wherein the controller is further configured to:
monitor an amount of renewable energy that is available from the at least one renewable energy resource to power the plurality of loads associated with the building; and
activate at least one graduated action to provide the renewable energy available from the at least one renewable energy resource to each load based on each corresponding load parameter for each load to provide the renewable energy to each corresponding load when the renewable energy is available to prevent accessing energy from the electric utility when the renewable energy is available.

8. The building automation system of claim 7, wherein the controller is further configured to:
prioritize each of the non-critical loads to determine a priority in activating each non-critical load when renewable energy is available from the at least one renewable energy resource to power each activated non-critical load associated with the building;
automatically activate a first non-critical load based on a first priority associated with the first non-critical load to activate the first non-critical load when the renewable energy is available from the at least one renewable energy resource;
continue to automatically activate each subsequent non-critical load based on each priority in activating each corresponding non-critical load until the activation of each subsequent non-critical load consumes the renewable energy available from the at least one renewable energy resource; and
maintain deactivation of each remaining non-critical load that is not previously activated based on the priority of activating each non-critical load when the renewable energy is not available from the at least one renewable energy resource.

9. The building automation system of claim 5, further comprising:
an electric battery storage system that is associated with the building and is configured to store electric energy available to the building.

10. The building automation system of claim 9, wherein the controller is further configured to:
monitor an amount of electric energy that is stored in the electric battery storage system to power the plurality of loads associated with the building; and
activate at least one graduated action to provide the stored electric energy available from the electric battery storage system to each load based on each corresponding load parameter for each load to provide the stored electric energy to each corresponding load when the stored electric energy is available to prevent accessing energy from the electric utility when the stored electric energy is available.

11. The building automation system of claim 10, wherein the controller is further configured to:
prioritize each of the non-critical loads to determine a priority in activating each non-critical load when stored electric energy is available from the electric battery storage system to power each activated non-critical load associated with the building;
automatically activate a first non-critical load based on a first priority associated with the first non-critical load to activate the first non-critical load when the stored electric energy is available from the electric battery storage system;
continue to automatically activate each subsequent non-critical load based on each priority in activating each corresponding non-critical load until the activation of each subsequent non-critical load consumes the renewable energy available from the electric battery storage system; and
maintain deactivation of each remaining non-critical load that is not previously activated based on the priority of activating each non-critical load when the stored electric energy is not available from the electric battery storage system.

12. A method for a building automation system that automatically adjusts a plurality of loads associated with a building based on a plurality of load parameters that are monitored throughout the building, comprising:
measuring by a plurality of loads monitoring sensors positioned in the building a corresponding load parameter associated with each corresponding load of the building, wherein each load parameter is indicative as to a current electric utility demand of the building based on current energy consumption of the loads associated with the building;
monitoring by a controller each load parameter measured by each corresponding load monitoring sensor to determine whether at least one load parameter deviates beyond at least one corresponding load parameter threshold; and
activating at least one graduated action when each load parameter deviates beyond the at least one corresponding load parameter threshold to automatically adjust the current energy consumption of the corresponding load that is deviated beyond the at least one corresponding load parameter threshold to maintain the current electric utility demand within an electric utility demand threshold, wherein the electric utility demand threshold is a peak demand allocated to the building by an electric utility to ensure that the peak demand for energy consumption of the building is satisfied.

13. The method of claim 12, wherein the measuring comprises:
measuring by a plurality of critical load sensors positioned in the building a corresponding critical load parameter associated with each corresponding critical load parameter associated with each corresponding critical load of the building, wherein each critical load parameter is indicative as to an impact on the current electric utility demand by each critical load based on current energy consumption of the critical loads associated with the building; and
measuring by a plurality of non-critical load sensors positioned in the building a corresponding non-critical load parameter associated with each corresponding non-critical load of the building, wherein each non-critical load parameter is indicative as to the impact on the current electric utility demand by each non-critical load based on energy consumption of the non-critical loads associated with the building.

14. The method of claim 13, further comprising:
monitoring each critical load parameter measured by each corresponding critical load monitoring sensor to determine whether at least one critical load parameter deviates beyond at least one corresponding critical load parameter threshold, wherein each critical load is a load associated with the building that cannot be deactivated to eliminate energy consumption by the critical load; and
activating at least one graduated action when each critical load parameter deviates beyond the at least one corresponding critical load parameter threshold to automatically adjust the current energy consumption of the corresponding critical load that is deviated beyond the at least one corresponding critical load parameter threshold without deactivating the corresponding critical load, wherein the activation of the at least one graduated action maintains the current electric utility demand within the electric utility demand threshold.

15. The method of claim 13, further comprising:
monitoring each non-critical load parameter threshold measured by each corresponding non-critical load monitoring sensor to determine whether at least one non-critical load parameter deviates beyond at least one corresponding non-critical load parameter threshold, wherein each non-critical load is a load associated with the building that can be deactivated to eliminate energy consumption by the non-critical load; and
activating at least one graduated action when each non-critical load parameter deviates beyond the at least one corresponding non-critical load parameter threshold to automatically adjust the current energy consumption of the corresponding non-critical load that is deviated beyond the at least one corresponding non-critical load parameter threshold, wherein the activation of the at least one graduated action maintains the current electric utility demand within the electric utility demand threshold.

16. The method of claim 15, further comprising:
prioritizing each of the non-critical loads to determine a priority in deactivating each non-critical load when the current electric utility demand exceeds the electric utility demand threshold;
automatically deactivating a first non-critical load based on a first priority associated with the first non-critical load to deactivate the first non-critical load when the current electric utility demand exceeds the electric utility demand threshold;
continuing to automatically deactivate each subsequent non-critical load based on each priority in deactivating each corresponding non-critical load until the deactivation of the each subsequent non-critical load decreases the electric utility demand below the electric utility demand threshold; and
maintaining activation of each remaining non-critical load that is not previously deactivated based on the priority of deactivating each non-critical load when the electric utility demand decreases below the electric utility demand threshold.

17. The method of claim 16, further comprising:
providing renewable energy to the building by at least one renewable energy source that is associated with the building, wherein the renewable energy provided by the at least one renewable energy source is energy consumed by the building that does not impact an increase in the electric utility demand of the building as the renewable energy is not provided by the electric utility.

18. The method of claim 16, further comprising:
monitoring an amount of renewable energy that is available from the at least one renewable resource to power the plurality of loads associated with the building; and
activating at least one graduated action to provide the renewable energy available from the at least one renewable energy resource to each load based on each corresponding load parameter for each load to provide the renewable energy to each corresponding load when the renewable energy is available to prevent accessing energy from the electric utility when the renewable energy is available.

19. The method of claim 18, further comprising:
prioritizing each of the non-critical loads to determine a priority in activating each non-critical load when renewable energy is available from the at least one renewable energy resource to power each activated non-critical load associated with the building;
automatically activating a first non-critical load based on a first priority associated with the first non-critical load to activate the first non-critical load when the renewable energy is available from the at least one renewable energy resource;
continuing to automatically activate each subsequent non-critical load based on each priority in activating each corresponding non-critical load until the activation of each subsequent non-critical load consumes the renewable energy available from the at least one renewable energy resource; and
maintaining deactivation of each remaining non-critical load that is not previously activated based on the priority of activating each non-critical load when the renewable energy is not available from the at least one renewable energy resource.

20. The method of claim 16, further comprising:
storing electric energy available to the building by an electric battery storage system that is associated with the building.

21. The method of claim 20, further comprising:
monitoring an amount of electric energy that is stored in the electric battery storage system to power the plurality of loads associated with the building; and
activating at least one graduated action to provide the stored electric energy available from the electric battery storage system to each load based on each corresponding load parameter for each load to provide the stored electric energy to each corresponding load when the stored electric energy is available to prevent accessing energy from the electric utility when the stored electric energy is available.

22. The method of claim 21, further comprising:
prioritizing each of the non-critical loads to determine a priority in activating each non-critical load when stored electric energy is available from the electric battery storage system to power each activated non-critical load associated with the building;
automatically activating a first non-critical load based on a first priority associated with the first non-critical load to activate the first non-critical load when the stored electric energy is available from the electric battery storage system;
continuing to automatically activate each subsequent non-critical load based on each priority in activating each corresponding non-critical load until the activation of each subsequent non-critical load consumes the renewable energy available from the electric battery storage system; and
maintaining deactivation of each remaining non-critical load that is not previously activated based on the priority of activating each non-critical load when the stored electric energy is not available from the electric battery storage system.
